(19) United States
(12) Patent Application Publication
(10) Pub. No.: US 2022/0310712 A1
(43) Pub. Date: Sep. 29, 2022

(54) METHOD FOR OPTIMIZING PIXEL ARRANGEMENT, LIGHT-TRANSMITTING DISPLAY PANEL AND DISPLAY PANEL

(71) Applicant: KunShan Go-Visionox Opto-Electronics Co., Ltd, Kunshan (CN)

(72) Inventors: Gaina ZHAO, Kunshan (CN); Rusheng LIU, Kunshan (CN); Rubo XING, Kunshan (CN); Hanquan YIN, Kunshan (CN); Junfei CAI, Kunshan (CN)

(73) Assignee: KunShan Go-Visionox Opto-Electronics Co., Ltd, Kunshan (CN)

(21) Appl. No.: 17/685,598

(22) Filed: Feb. 2, 2022

Related U.S. Application Data
(63) Continuation of application No. PCT/CN2021/071414, filed on Jan. 13, 2021.

(30) Foreign Application Priority Data
Mar. 17, 2020 (CN) 202010184309.6

(51) Int. Cl. H01L 27/32

(52) U.S. Cl. CPC H01L 27/3218; H01L 27/3216

(57) ABSTRACT

A method and apparatus for optimizing a pixel arrangement, a light-transmitting display panel, and a display panel. A light-transmitting display panel, includes: an array substrate; and a light-emitting layer positioned on the array substrate, the light-emitting layer comprising a plurality of pixel units, a plurality of first electrodes of respective sub-pixels in the plurality of pixel units being arranged in a pattern, and a combination of graphic parameters and position parameters of the plurality of first electrodes arranged in the pattern enabling zero-order diffraction spot energy of the light-transmitting display panel and light transmission energy of the light-transmitting display panel satisfying a following relationship expression:

$$\frac{{I}_{0}}{{I}_{x}} \geq 85 \%$$

I₀ represents the zero-order diffraction spot energy of the light-transmitting display panel, and Iₓ represents the light transmission energy of the light-transmitting display panel.

### CROSS-REFERENCE TO RELATED APPLICATIONS

This application is a continuation of International Application No. PCT/CN2021/071414 filed on Jan. 13, 2021, which claims the priority to Chinese patent application No. 202010184309.6, entitled “METHOD AND APPARATUS FOR OPTIMIZING PIXEL ARRANGEMENT, LIGHT-TRANSMITTING DISPLAY PANEL AND DISPLAY PANEL” and filed on Mar. 17, 2020, both of which are incorporated herein by reference in their entireties.

### TECHNICAL FIELD

This application relates to the field of display technology, and particularly to a method and apparatus for optimizing a pixel arrangement, a light-transmitting display panel, and a display panel.

### BACKGROUND

With rapid development of electronic devices, users are requiring to have higher and higher screen-to-body ratios, so that the industry has shown more and more interest in all-screen displays of electronic devices.

There is a need for electronic devices, such as mobile phones and tablets, to have front-facing cameras, earpieces, and infrared sensing components etc. integrated thereon. In the prior art, notches or holes may be provided on display screens, so that external light can enter photosensitive components under the screens through the notches or holes on the screens. However, all such display screens are not actual all-screen displays, since not all regions across the screens can be used to display, for example, regions corresponding to front-facing cameras cannot be used to display pictures.

### SUMMARY

The present application provides a method for optimizing a pixel arrangement in a first aspect. The method includes: constructing an initial pixel arrangement structure model, a first electrode of each sub-pixel in the initial pixel arrangement structure model having an initial graphic parameter and an initial position parameter; and adjusting at least one of initial graphic parameters and initial position parameters of at least a part of first electrodes in the initial pixel arrangement structure model to obtain an optimized pixel arrangement structure model, a ratio of zero-order diffraction spot energy of the optimized pixel arrangement structure model to light transmission energy of the optimized pixel arrangement structure model being greater than or equal to 85%.

In a possible implementation of the first aspect, after obtaining the optimized pixel arrangement structure model, the method further includes: setting a graphic parameter and a position parameter for each first electrode in a target light-transmitting display panel, according to a corresponding graphic parameter and position parameter of a corresponding first electrode in the optimized pixel arrangement structure model.

In a possible implementation of the first aspect, constructing the initial pixel arrangement structure model includes: acquiring a pixel arrangement structure of a target light-transmitting display panel and an initial graphic parameter and an initial position parameter of a first electrode of each sub-pixel of the target light-transmitting display panel; and constructing the initial pixel arrangement structure model, according to the pixel arrangement structure of the target light-transmitting display panel and the initial graphic parameter and the initial position parameter of the first electrode of each sub-pixel of the target light-transmitting display panel.

In a possible implementation of the first aspect, adjusting at least one of initial graphic parameters and initial position parameters of at least a part of first electrodes in the initial pixel arrangement structure model to obtain the optimized pixel arrangement structure model, a ratio of zero-order diffraction spot energy of the optimized pixel arrangement structure model to light transmission energy of the optimized pixel arrangement structure model is greater than or equal to 85%, includes: determining whether a ratio of zero-order diffraction spot energy of the initial pixel arrangement structure model to light transmission energy of the initial pixel arrangement structure model is greater than or equal to 85% or not under conditions of different irradiation wavelengths, fields of view, and object distances; under a condition that the ratio is not greater than or equal to 85%, adjusting continuously at least one of the initial graphic parameters and the initial position parameters of at least a part of the first electrodes in the initial pixel arrangement structure model, until the optimized pixel arrangement structure model is obtained, enabling the ratio of the zero-order diffraction spot energy of the optimized pixel arrangement structure model to the light transmission energy of the optimized pixel arrangement structure model to be greater than or equal to 85% under the conditions of different irradiation wavelengths, fields of view, and object distances.

An embodiment of the present application provides a light-transmitting display panel. The light-transmitting display panel includes: an array substrate, and a light-emitting layer positioned on the array substrate, the light-emitting layer comprising a plurality of pixel units each pixel unit comprising a plurality of sub-pixels each having a first electrode, the first electrodes of the sub-pixels in the plurality of pixel units being arranged in a pattern, the plurality of first electrodes arranged in the pattern having a combination of graphic parameters and position parameters, and zero-order diffraction spot energy of the light-transmitting display panel and light transmission energy of the light-transmitting display panel satisfying a following relationship expression:

$$\frac{{I}_{0}}{{I}_{x}} \geq 85 \%$$

wherein I₀ represents the zero-order diffraction spot energy of the light-transmitting display panel, and Iₓ represents the light transmission energy of the light-transmitting display panel.

According to the method for optimizing the pixel arrangement of the embodiment of the present application, a ratio of zero-order diffraction spot energy of the optimized pixel arrangement structure model to light transmission energy of the optimized pixel arrangement structure model is enabled to be greater than or equal to 85% (i.e., a proportion of the zero-order diffraction spot energy is increased and a proportion of non-zero-order diffraction spot energy is decreased), by constructing an initial pixel arrangement structure model and adjusting at least one of initial graphic parameters and initial position parameters of first electrodes of at least a part of sub-pixels in the initial pixel arrangement structure model, so as to obtain graphic parameters and position parameters of the first electrodes that can mitigate the diffraction phenomenon.

According to the light-transmitting display panel of the embodiment of the present application, a combination of the graphic parameters and the position parameters of the first electrodes in the light-transmitting display panel enables a ratio of zero-order diffraction spot energy of the light-transmitting display panel to light transmission energy of the light-transmitting display panel to be greater than or equal to 85% (i.e., a proportion of the zero-order diffraction spot energy is increased and a proportion of non-zero-order diffraction spot energy is decreased). Therefore, the diffraction phenomenon of the light-transmitting display panel can be mitigated, and a photosensitive quality of a photosensitive component (for example, a camera) integrated under the screen can be improved.

### BRIEF DESCRIPTION OF THE DRAWINGS

Other features, objects and advantages of the present application will be apparent, after reading the detailed description of non-limiting embodiments which is described with reference to the accompanying drawings, where the same or similar reference signs indicate the same or similar features. The drawings are not necessarily drawn to the actual scale.

FIG. 1 shows a schematic flowchart of a method for optimizing a pixel arrangement according to an embodiment of the present application;

FIG. 2 shows a schematic structural diagram of an apparatus for optimizing a pixel arrangement according to an embodiment of the present application;

FIG. 3 shows a schematic structural diagram of a light-transmitting display panel according to an embodiment of the present application;

FIG. 4 shows a partial enlarged schematic top view of a first example of a Q region in FIG. 3;

FIG. 5 shows a partial enlarged schematic top view of a second example of the Q region in FIG. 3;

FIG. 6 shows a partial enlarged schematic top view of a third example of the Q region in FIG. 3;

FIG. 7 shows a partial enlarged schematic top view of a fourth example of the Q region in FIG. 3; and

FIG. 8 is a schematic top view of a display panel according to an embodiment of the present application.

### DETAILED DESCRIPTION

Features and exemplary embodiments of various aspects of the present application will be described in detailed below. In order to make the objects, technical solutions and advantages of the present application clearer, the present application is further described in details below with reference to the accompany drawings and specific embodiments. It should be understood that the specific embodiments described herein are only for illustration of the present application, and are not for limiting the present application. For those skilled in the art, the present application can be implemented without some of those specific details. The below description of embodiments is only for providing better understanding of the present application by showing examples of the present application.

In an electronic device, such as a mobile phone and a tablet etc., there is a need to integrate photosensitive components (e.g., front-facing cameras, infrared light sensors, and proximity light sensors) on the side where a display panels is provided. In some embodiments, a light-transmitting display area may be provided on the above-described electronic device, and the photosensitive components may be arranged on the back of the light-transmitting display area, so that all-screen display for the electronic device can be realized, while proper operations of the photosensitive components can be guaranteed.

At present, there is still a serious diffraction phenomenon in a light-transmitting display region of a display panel, which affects a photosensitive quality of an under-screen photosensitive component.

In order to solve the above problem, embodiments of the present application provide a method and apparatus for optimizing a pixel arrangement, a light-transmitting display panel, and a display panel. Embodiments of the method and apparatus for optimizing the pixel arrangement, the light-transmitting display panel, and the display panel will be illustrated in details below in conjunction with the accompanying drawings.

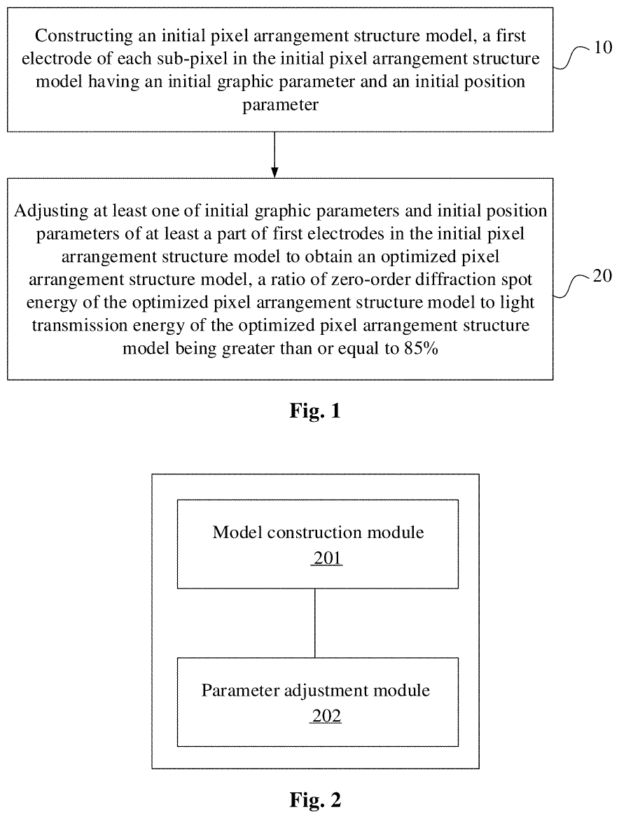

FIG. 1 shows a schematic flowchart of a method for optimizing a pixel arrangement according to an embodiment of the present application. As shown in FIG. 1, the method for optimizing the pixel arrangement includes Step 10 and Step 20.

In Step 10, an initial pixel arrangement structure model is constructed. A first electrode of each sub-pixel in the initial pixel arrangement structure model has an initial graphic parameter and an initial position parameter.

In some embodiments, any pixel arrangement structure may be selected, and the initial graphic parameter and the initial position parameter may be set for the first electrode of each sub-pixel in the pixel arrangement structure, and in turn, the initial pixel arrangement structure model may be constructed in a simulation software.

In some other embodiments, a pixel arrangement structure of a target light-transmitting display panel and a graphic parameter and a position parameter of a first electrode of each sub-pixel of the target light-transmitting display panel may be obtained; the initial pixel arrangement structure model may be constructed according to the pixel arrangement structure and the graphic parameter and the position parameter of the first electrode of each sub-pixel of the target light-transmitting display panel. The target light-transmitting display panel may be an actual light-transmitting display panel produced according to a predetermined process, the graphic parameter and position parameter of the first electrode of each sub-pixel of the target light-transmitting display panel may be imported into a simulation software, and a digital model of the target light-transmitting display panel may be constructed using the simulation software. The simulation software may be, for example, comsol, fdtd, rsoft and so forth. The target light-transmitting display panel may include first electrode and may also include an array substrate, various wiring structures, light-emitting structures, and second electrodes, etc. The constructed initial pixel arrangement structure model may include respective film layer parameters of the target light-transmitting display panel.

As compared with producing target light-transmitting display panels under various parameters practically to obtain optimized parameters, costs can be saved and the efficiency can be improved, by constructing the initial pixel arrangement structure model of the target light-transmitting display panel and then obtaining the optimized parameters corresponding to the target light-transmitting display panel using the initial pixel arrangement structure model

In Step 20, at least one of initial graphic parameters and initial position parameters of at least a part of first electrodes in the initial pixel arrangement structure model is adjusted, to obtain an optimized pixel arrangement structure model. A ratio of zero-order diffraction spot energy of the optimized pixel arrangement structure model to light transmission energy of the optimized pixel arrangement structure model is greater than or equal to 85%.

Exemplarily, the greater the ratio of the zero-order diffraction spot energy of the optimized pixel arrangement structure model to the light transmission energy of the optimized pixel arrangement structure model, the more the mitigation of the diffraction effect of the display panel adopting the optimized pixel arrangement structure, and thus the more the improvement of the photosensitive quality of the photosensitive component positioned on the non-light emitting side of the display panel.

In some embodiments, Step 20 may specifically include:

determining whether a ratio of zero-order diffraction spot energy of the initial pixel arrangement structure model to light transmission energy of the initial pixel arrangement structure model is greater than or equal to 85% or not under conditions of different irradiation wavelengths, fields of view, and object distances;

if not, adjusting continuously at least one of the initial graphic parameters and the initial position parameters of at least a part of the first electrodes in the initial pixel arrangement structure model, until the optimized pixel arrangement structure model is obtained, enabling the ratio of the zero-order diffraction spot energy of the optimized pixel arrangement structure model to the light transmission energy of the optimized pixel arrangement structure model to be greater than or equal to 85% under the conditions of different irradiation wavelengths, fields of view, and object distances.

Irradiation wavelengths may range from 400 nanometers to 800 nanometers. A field of view may be a field of photographic view of an under-screen photosensitive component, such as a field of view of a camera. A virtual object model may be constructed, and various distances between the virtual object model and the initial pixel arrangement structure model may be set. The light transmission energy is energy of light that can transmit through the pixel arrangement structure model.

Exemplarily, it is determined firstly whether the ratio of the zero-order diffraction spot energy of the initial pixel arrangement structure model to the light transmission energy of the initial pixel arrangement structure model is greater than or equal to 85% or not under the conditions of different irradiation wavelengths, fields of view, and object distances; if the initial pixel arrangement structure model meets the above condition, the initial graphic parameters and the initial position parameters of the first electrodes of the initial pixel arrangement structure model are the optimal parameters; if the initial pixel arrangement structure model does not meet the above condition, at least one of the initial graphic parameters and the initial position parameters of the first electrodes in the initial pixel arrangement structure model is adjusted continuously, and it is determined whether the adjusted pixel arrangement structure model meets the above condition or not after each adjustment, until an optimized pixel arrangement structure model is obtained.

According to the embodiments of the present application, the ratio of the zero-order diffraction spot energy to the light transmission energy for the finally obtained and optimized pixel arrangement structure model is greater than or equal to 85% under the conditions of different irradiation wavelengths, fields of view, and object distances, so as to obtain the graphic parameters and the position parameters of the first electrodes that can mitigate the diffraction phenomenon under various conditions.

In some embodiments, after Step 20, the method may further include setting a graphic parameter and a position parameter for each first electrode in the target light-transmitting display panel, according to a corresponding graphic parameter and position parameter of a corresponding first electrode in the optimized pixel arrangement structure model.

After obtaining the optimized graphic parameters and position parameters of the first electrodes, an actual target light-transmitting display panel may be produced according to the optimized graphic parameters and position parameters of the first electrodes, so that the ratio of the zero-order diffraction spot energy to the light transmission energy of the target light-transmitting display panel is greater than or equal to 85%. A proportion of the zero-order diffraction spot energy can be increased and a proportion of non-zero-order diffraction spot energy can be decreased. Therefore, the diffraction phenomenon of the target light-transmitting display panel can be mitigated, and a photosensitive quality of a photosensitive component integrated on the non-light-emitting side of the target light-transmitting display panel can be improved.

In the above embodiments, the initial graphic parameters may be shape parameters and size parameters of the first electrodes, and the initial position parameters may be coordinate parameters of the first electrodes or relative position parameters between the first electrodes.

In addition, the inventors found that periodically arranged anodes in the display panel have a greater impact on the diffraction of the light-transmitting area. By adjusting a shape, size and arrangement of an anode corresponding to each sub-pixel, the energy of the non-zero-order diffraction spot can be decreased, and the energy of the zero-order diffraction spot can be increased, so that more energy is concentrated on a geometric image point to mitigate the diffraction effect and improve an imaging quality of an under-screen camera. Therefore, in the above embodiments, a first electrode may be an anode.

According to the method for optimizing the pixel arrangement of the embodiment of the present application, a ratio of zero-order diffraction spot energy of the obtained and optimized pixel arrangement structure model to light transmission energy of the optimized pixel arrangement structure model is enabled to be greater than or equal to 85% (i.e., a proportion of the zero-order diffraction spot energy is increased and a proportion of non-zero-order diffraction spot energy is decreased), by constructing an initial pixel arrangement structure model and adjusting at least one of initial graphic parameters and initial position parameters of first electrodes of at least a part of sub-pixels in the initial pixel arrangement structure model, so as to obtain graphic parameters and position parameters of the first electrodes that can mitigate the diffraction phenomenon.

FIG. 2 shows a schematic structural diagram of an apparatus for optimizing a pixel arrangement according to an embodiment of the present application. As shown in FIG. 2, the apparatus for optimizing the pixel arrangement provided by the embodiment of the present application includes following modules.

A model construction module 201 is configured to construct an initial pixel arrangement structure model. First electrodes of respective sub-pixels in the initial pixel arrangement structure model form an initial first electrode matrix jointly. Each of the first electrodes has an initial graphic parameter and an initial position parameter.

A parameter adjustment module 202 is configured to adjust at least one of initial graphic parameters and initial position parameters of at least a part of first electrodes in the initial pixel arrangement structure model to obtain an optimized pixel arrangement structure model. A ratio of zero-order diffraction spot energy of the optimized pixel arrangement structure model to light transmission energy of the optimized pixel arrangement structure model is greater than or equal to 85%.

In some embodiments, the structure for optimizing the pixel arrangement may further include a parameter setting module, configured to set a graphic parameter and a position parameter for each first electrode in a target light-transmitting display panel, according to a corresponding graphic parameter and position parameter of a corresponding first electrode in the optimized pixel arrangement structure model.

In some embodiments, the model construction module 201 is specifically configured to:

acquire a pixel arrangement structure of a target light-transmitting display panel and a graphic parameter and a position parameter of a first electrode of each sub-pixel of the target light-transmitting display panel; and

construct the initial pixel arrangement structure model, according to the pixel arrangement structure of the target light-transmitting display panel and the graphic parameter and the position parameter of the first electrode of each sub-pixel of the target light-transmitting display panel.

In some embodiments, the parameter adjustment module 202 is specifically configured to:

determine whether a ratio of zero-order diffraction spot energy of the initial pixel arrangement structure model to light transmission energy of the initial pixel arrangement structure model is greater than or equal to 85% or not under conditions of different irradiation wavelengths, fields of view, and object distances;

if not, adjust continuously at least one of the initial graphic parameters and the initial position parameters of at least a part of the first electrodes in the initial pixel arrangement structure model, until the optimized pixel arrangement structure model is obtained, enabling the ratio of the zero-order diffraction spot energy of the optimized pixel arrangement structure model to the light transmission energy of the optimized pixel arrangement structure model to be greater than or equal to 85% under the conditions of different irradiation wavelengths, fields of view, and object distances.

According to the apparatus for optimizing the pixel arrangement of the embodiment of the present application, a ratio of zero-order diffraction spot energy of the obtained and optimized pixel arrangement structure model to light transmission energy of the optimized pixel arrangement structure model is enabled to be greater than or equal to 85% (i.e., a proportion of the zero-order diffraction spot energy is increased and a proportion of non-zero-order diffraction spot energy is decreased), by constructing an initial pixel arrangement structure model and adjusting at least one of initial graphic parameters and initial position parameters of first electrodes of at least a part of sub-pixels in the initial pixel arrangement structure model, so as to obtain graphic parameters and position parameters of the first electrodes that can mitigate the diffraction phenomenon.

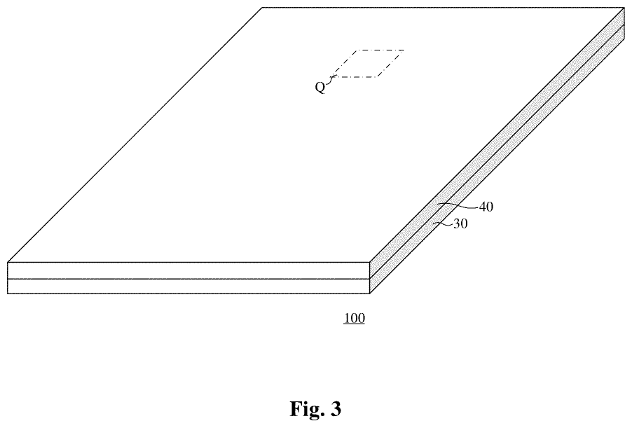

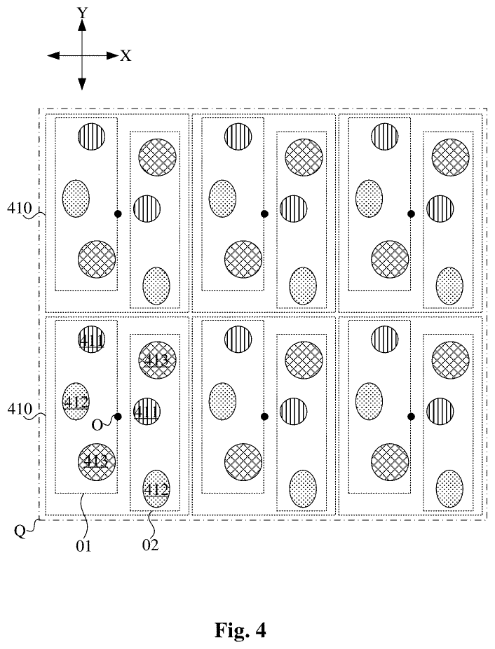

FIG. 3 shows a schematic structural diagram of a light-transmitting display panel according to an embodiment of the present application. FIG. 4 to FIG. 7 show partial enlarged views of the Q region in FIG. 3. In order to show a structure of the first electrode clearly, other structures of a light-transmitting display panel 100 are not drawn explicitly in FIG. 4 to FIG. 7.

As shown in FIG. 3 and FIG. 4 to FIG. 7, the light-transmitting display panel 100 includes an array substrate 30 and a light-emitting layer 40. The light emitting layer 40 is positioned on the array substrate 30. The light-emitting layer 40 includes pixel units 410. First electrodes of respective sub-pixels in the pixel units 410 are arranged in a pattern. The plurality of first electrodes arranged in the pattern have a combination of graphic parameters and position parameters, and zero-order diffraction spot energy of the light-transmitting display panel and light transmission energy of the light-transmitting display panel satisfy a following relationship expression:

$$\frac{{I}_{0}}{{I}_{x}} \geq 85 \%$$

wherein I₀ represents the zero-order diffraction spot energy of the light-transmitting display panel, and Iₓ represents the light transmission energy of the light-transmitting display panel.

A combination of graphic parameters and position parameters of the first electrodes arranged in the pattern enables zero-order diffraction spot energy of the light-transmitting display panel 100 and light transmission energy of the light-transmitting display panel to satisfy a relationship expression (1):

$$\frac{{I}_{0}}{{I}_{x}} \geq 85 \% \qquad ( 1 )$$

In the expression (1), I₀ represents the zero-order diffraction spot energy of the light-transmitting display panel, and Iₓ represents the light transmission energy of the light-transmitting display panel.

The light-transmitting display panel 100 may be an Organic Light Emitting Diode (OLED) display panel.

In some embodiments, the array substrate 30 may include pixel circuits, wiring structures, and so on. In order to improve the light transmittance of the light-transmitting display panel 100, the pixel circuits in the array substrate 30 may be arranged as exactly under respective sub-pixels as possible, and the wiring structures may be arranged deviously so as to occupy areas between the sub-pixels as less as possible. A luminescent material of a sub-pixel is vapor-deposited on an anode with low light transmittance, and a cathode of the sub-pixel is formed of a whole layer of material. Further, the inventors found that anodes periodically arranged in the display panel have a greater impact on the diffraction of the light-transmitting area. By configuring a shape, size and arrangement of an anode corresponding to each sub-pixel, the energy of the non-zero-order diffraction spot can be decreased, and the energy of the zero-order diffraction spot can be increased, so that more energy is concentrated on a geometric image point to mitigate the diffraction effect and improve an imaging quality of an under-screen camera. Therefore, a first electrode may be an anode of a sub-pixel.

Exemplarily, the graphic parameters and position parameters of the respective first electrodes in the light-transmitting display panel may be the optimized parameters obtained according to the above-mentioned method for optimizing the pixel arrangement.

According to the light-transmitting display panel of the embodiment of the present application, a combination of the graphic parameters and the position parameters of the first electrodes in the light-transmitting display panel enables a ratio of zero-order diffraction spot energy of the light-transmitting display panel to light transmission energy of the light-transmitting display panel to be greater than or equal to 85%, i.e., a proportion of the zero-order diffraction spot energy is increased and a proportion of non-zero-order diffraction spot energy is decreased. Therefore, the diffraction phenomenon of the light-transmitting display panel can be mitigated, and a photosensitive quality of a photosensitive component (for example, a camera) integrated under the screen can be improved.

In some embodiments, a sub-pixel of each color may include a first electrode, a light-emitting structure, and a second electrode that are stacked sequentially. One of the first electrode and the second electrode is an anode, and the other one is a cathode. In the embodiment, an example that the first electrode is the anode and the second electrode is the cathode is described for illustration.

The light-emitting structure may include an OLED light-emitting layer. According to a design requirement of the light-emitting structure, the OLED light-emitting layer may further include at least one of a hole injection layer, a hole transport layer, an electron injection layer, or an electron transport layer.

In some embodiments, the first electrode may include an Indium Tin Oxide (ITO) layer or an Indium Zinc Oxide layer. In some embodiments, the first electrode may be a reflective electrode, including a first light-transmitting conductive layer, a reflective layer on the first light-transmitting conductive layer, and a second light-transmitting conductive layer on the reflective layer. The first light-transmitting conductive layer and the second light-transmitting conductive layer may be the ITO layer, the Indium Zinc Oxide layer, etc., and the reflective layer may be a metal layer, for example, a layer made of silver.

In some embodiments, the second electrode may include a magnesium-silver alloy layer. In some embodiments, the second electrode may be interconnected as a common electrode.

In some embodiments, as further shown in FIG. 4, each pixel unit 410 includes a first pixel group 01 and a second pixel group 02 distributed along a first direction X, the first pixel group 01 includes a first color sub-pixel, a second color sub-pixel, and a third color sub-pixel distributed along a second direction Y, and the second pixel group 02 includes a third color sub-pixel, a first color sub-pixel, and a second color sub-pixel distributed along the second direction Y. The first direction X intersects the second direction Y. A shape of an orthographic projection of a first electrode 411 of the first color sub-pixel and a shape of an orthographic projection of a first electrode 413 of the third color sub-pixel on the array substrate are circles, and a shape of an orthographic projection of a first electrode 412 of the second color sub-pixel on the array substrate is an ellipse. Further, a diameter of the first electrode 412 of the first color sub-pixel ranges from 5 micron (μm) to 25 μm, a diameter of the first electrode 413 of the third color sub-pixel ranges from 8 μm to 30 μm, a long axis of the first electrode 412 of the second color sub-pixel ranges from 10 μm to 30 μm, and a short axis of the first electrode 412 of the second color sub-pixel ranges from 8 μm to 20 μm.

Exemplarily, before optimization, shape of orthographic projections of first electrodes of sub-pixels of the three colors of an original light-transmitting display panel on the array substrate are all ellipses. At this time, a proportion of energy of the non-zero-order diffraction spot of the light-transmitting display panel is relatively high, and the diffraction phenomenon is obvious. The present application optimizes configuration of the first electrodes of the original light-transmitting display panel, adjusts shapes and sizes of first electrodes of sub-pixels of some color(s), and further disrupts a periodic structure of the first electrodes, so that a proportion of energy of the zero-order diffraction spot of the light-transmitting display panel can be increased, and the diffraction phenomenon of the light-transmitting display panel can be mitigated.

In some embodiments, a coordinate of a central point O of each pixel unit 410 may be set firstly. Further, a distance from the first electrode 411 of the first color sub-pixel in the first pixel group 01 to the central point O of the pixel unit 410 in the first direction X ranges from 10 μpm to 30 μm, and a distance from the first electrode 411 of the first color sub-pixel in the first pixel group 01 to the central point O of the pixel unit 410 in the second direction Y ranges from 45 μm to 65 μm; a distance from a central point of the first electrode 412 of the second color sub-pixel in the first pixel group 01 to the central point O of the pixel unit 410 in the first direction X ranges from 25 μm to 40 μm, and a distance from a central point of the first electrode 412 of the second color sub-pixel in the first pixel group 01 to the central point O of the pixel unit 410 in the second direction Y ranges from 20 μm to 40 μm; a distance from a central point of the first electrode 413 of the third color sub-pixel in the first pixel group 01 to the central point O of the pixel unit 410 in the first direction X ranges from 10 μpm to 30 μm, and a distance from the central point of the first electrode 413 of the third color sub-pixel in the first pixel group 01 to the central point O of the pixel unit 410 in the second direction Y ranges from 15 μpm to 30 μm.

And/or, a distance from first electrode 411 of the first color sub-pixel in the second pixel group 02 to the central point O of the pixel unit 410 in the first direction X ranges from 10 μm to 25 μm, and a distance from first electrode 411 of the first color sub-pixel in the second pixel group 02 to the central point O of the pixel unit 410 in the second direction Y ranges from 0 μm to 20 μm; a distance from a central point of the first electrode 412 of the second color sub-pixel in the second pixel group 02 to the central point O of the pixel unit 410 in the first direction X ranges from 25 μm to 40 μm, and a distance from a central point of the first electrode 412 of the second color sub-pixel in the second pixel group 02 to the central point O of the pixel unit 410 in the second direction Y ranges from 30 μm to 50 μm; a distance from a central point of the first electrode 413 of the third color sub-pixel in the second pixel group 02 to the central point O of the pixel unit 410 in the first direction X ranges from 25 μm to 40 μm, and a distance from a central point of the first electrode 413 of the third color sub-pixel in the second pixel group 02 to the central point O of the pixel unit 410 in the second direction Y ranges from 40 μm to 55 μm.

This arrangement further disrupts the periodic structure of the first electrodes, so that the proportion of energy of the zero-order diffraction spot of the light-transmitting display panel can be increased and the diffraction phenomenon of the light-transmitting display panel can be mitigated.

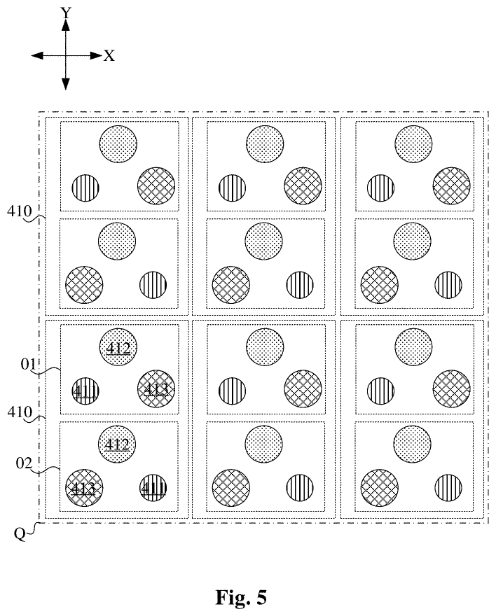

In some embodiments, as shown in FIG. 5, each pixel unit 410 includes two pixel groups distributed along the second direction Y, i.e., a first pixel group 01 and a second pixel group 02. Each pixel group includes one first color sub-pixel, one second color sub-pixel, and one third color sub-pixel. Central points of first electrodes of the three sub-pixels in each pixel group, when connected by lines, form a triangle. An arrangement structure of one of the pixel groups after being inverted by 180 degrees in the first direction X may be identical to an arrangement structure of the other one of the pixel groups in the pixel unit 410. The first direction X intersects the second direction Y. A shape of an orthographic projection of the first electrode 411, 412 or 413 of each sub-pixel on the array substrate is a circle. Further, a diameter of the first electrode 411 of the first color sub-pixel ranges from 5 μpm to 25 μm, a diameter of the first electrode 412 of the second color sub-pixel ranges from 10 μm to 30 μm, and a diameter of the first electrode 413 of the third color sub-pixel ranges from 10 μm to 30 μm

And/or, a distance between every two of the central points of first electrodes 411, 412 and 413 of the sub-pixels of the three colors in each of the pixel groups is 15 μm to 50 μm, and/or the central points of first electrodes 411, 412 and 413 of the sub-pixels of the three colors in each of the pixel groups, when connected by lines, form an isosceles triangle or an equilateral triangle.

Exemplarily, before optimization, orthographic projections of first electrodes of sub-pixels of the three colors of an original light-transmitting display panel on the array substrate are all rhombuses. At this time, a proportion of energy of the non-zero-order diffraction spot of the light-transmitting display panel is relatively high, and the diffraction phenomenon is obvious. The present application optimizes configuration of the first electrodes of the original light-transmitting display panel, adjusts shapes and sizes of the first electrodes, and further disrupts a periodic structure of the first electrodes, so that a proportion of energy of the zero-order diffraction spot of the light-transmitting display panel can be increased, and the diffraction phenomenon of the light-transmitting display panel can be mitigated.

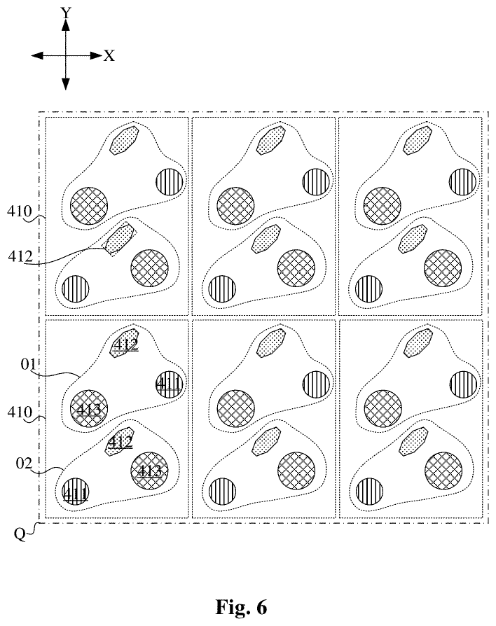

In some other embodiments, as shown in FIG. 6, each pixel unit 410 includes two pixel groups distributed along the second direction Y, i.e., a first pixel group 01 and a second pixel group 02. Each pixel group includes one first color sub-pixel, one second color sub-pixel, and one third color sub-pixel. Central points of first electrodes 411, 412 and 413 of the three sub-pixels in each of the pixel groups, when connected by lines, form a triangle. An arrangement structure of one of the pixel groups after being inverted by 180 degrees in the first direction X may be identical to an arrangement structure of the other one of the pixel groups in the pixel unit 410. The first direction intersects the second direction Y. A shape of an orthographic projection of a first electrode 411 of the first color sub-pixel and a shape of an orthographic projection of the first electrode 413 of the third color sub-pixel on the array substrate are circles, a shape of an orthographic projection of the first electrode 412 of the second color sub-pixel on the array substrate is an octagon, and virtual extension lines of four sides of the octagon constitute a rectangle.

Further, a diameter of the first electrode 411 of the first color sub-pixel ranges from 5 μm to 25 μm, a diameter of the first electrode 413 of the third color sub-pixel ranges from 10 μm to 30 μm, the long side and short side of a rectangle corresponding to the first electrode 412 of the second color sub-pixel range from 10 μm to 30 μm and 5 μm to 25 μm, respectively. And/or a distance between central points of first electrodes 411 of two first color sub-pixels is 30 μm to 90 μm, a distance between central points of first electrodes 412 of two second color sub-pixels is 25 μm to 60 μm, a distance between central points of first electrodes 413 of two third color sub-pixels is 25 μm to 60 μm; and/or the central points of the first electrodes 411 of the two first color sub-pixels and the central points of the first electrodes 413 of the two third color sub-pixels, when connected by lines, constitute a parallelogram.

Exemplarily, before optimization, an orthographic projection of the first electrode of the first color sub-pixel of an original light-transmitting display panel on the array substrate is a rhombus, and orthographic projections of the first electrodes of the second color sub-pixel and the third color sub-pixel on the array substrate are both octagons. At this time, a proportion of energy of the non-zero-order diffraction spot of the light-transmitting display panel is relatively high, and the diffraction phenomenon is obvious. The present application optimizes configuration of the first electrodes of the original light-transmitting display panel, adjusts shapes and sizes of first electrodes of sub-pixels of some color(s), and further disrupts a periodic structure of the first electrodes, so that a proportion of energy of the zero-order diffraction spot of the light-transmitting display panel can be increased, and the diffraction phenomenon of the light-transmitting display panel can be mitigated.

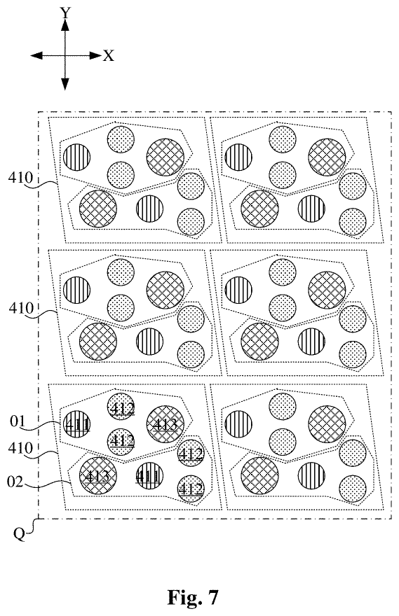

In some embodiments, as shown in FIG. 7, each pixel unit 410 includes a first pixel group 01 and a second pixel group 02 distributed along the second direction Y. The first pixel group 01 includes one first color sub-pixel, two second color sub-pixels, and one third color sub-pixel distributed along the first direction X. The second pixel group 02 includes one third color sub-pixel, one first color sub-pixel, and two second color sub-pixels distributed along the first direction X. The two second color sub-pixels in each of the first pixel group 01 and the second pixel group 02 are distributed along the second direction Y. The first direction X intersects the second direction Y. A shape of an orthographic projection of the first electrode 411, 412 or 413 of each sub-pixel on the array substrate is a circle

Further, a diameter of the first electrode 411 of the first color sub-pixel ranges from 5 μm to 30 μm, a diameter of the first electrode 412 of each second color sub-pixel ranges from 5 μm to 30 μm, and a diameter of the first electrode 413 of the third color sub-pixel ranges from 10 μm to 40 μm. And/or, a distance between central points of the first electrodes 411 of two first color sub-pixels is 50 μm to 250 μm, a distance between central points of the first electrodes 412 of the two second color sub-pixels in each pixel group is 10 μm to 30 μm, a distance between central points of the first electrodes 413 of two third color sub-pixels is 10 μm to 60 μm. And/or, the pixel unit 410 as a whole constitutes a parallelogram.

Exemplarily, before optimization, orthographic projections of first electrodes of a first color sub-pixel and a third color sub-pixel of an original light-transmitting display panel on the array substrate are both hexagons, and orthographic projections of the first electrodes of the second color sub-pixels are both pentagons. At this time, a proportion of energy of the non-zero-order diffraction spot of the light-transmitting display panel is relatively high, and the diffraction phenomenon is obvious. The present application optimizes configuration of the first electrodes of the original light-transmitting display panel, adjusts shapes and sizes of first electrodes of respective sub-pixels, and further disrupts a periodic structure of the first electrodes, so that a proportion of energy of the zero-order diffraction spot of the light-transmitting display panel can be increased, and the diffraction phenomenon of the light-transmitting display panel can be mitigated.

Further, as shown in FIG. 7, a distribution density of the pixel units 410 can be set greater to mitigate the diffraction phenomenon of the light-transmitting display panel.

In the above examples, the first color sub-pixel may be a red sub-pixel, the second color sub-pixel may be a green sub-pixel, and the third color sub-pixel may be a blue sub-pixel.

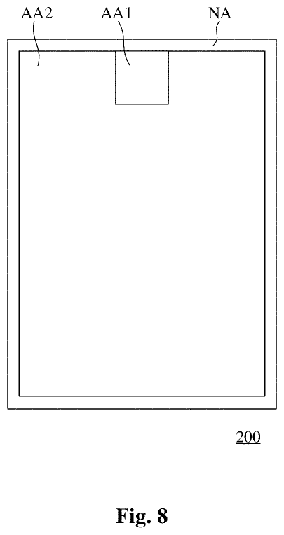

FIG. 8 is a schematic top view of a display panel according to an embodiment of the present application. As shown in FIG. 8, the display panel 200 includes a first display area AA1, a second display area AA2, and a non-display area NA surrounding the first display area AA1 and the second display area AA2. A light transmittance of the first display area AA1 is greater than that of the second display area AA2.

Here, it is preferable that the light transmittance of the first display area AA1 is greater than or equal to 15%. In order to ensure that the light transmittance of the first display area AA1 is greater than 15%, even greater than 40%, or even more, light transmittance of at least some of functional film layers of the display panel 200 of the embodiment of the present application is greater than 80% or even greater than 85%.

The display panel 200 may include a first surface S1 and a second surface S2 that are opposite to each other. The first surface S1 is a display surface. A photosensitive component may be positioned on the second surface side of the display panel 200. The photosensitive component may correspond to the position of the first display area AA1.

The photosensitive component may be image acquisition equipment that may be used to acquire external image information. In this embodiment, the photosensitive component is Complementary Metal Oxide Semiconductor (CMOS) image acquisition equipment, and in some other embodiments, the photosensitive component may be another type of image acquisition equipment, such as Charge-coupled Device (CCD) image acquisition equipment. It may be understood that the photosensitive component may not be limited to the image acquisition equipment, and for example, in some embodiments, the photosensitive component may be a light sensor such as an infrared sensor, a proximity sensor, an infrared lens, a flood light sensor, an ambient light sensor, and a dot matrix projector etc. In addition, other elements such as a receiver or a speaker, may also be integrated on the second surface of the display panel 200.

According to the display panel of the embodiment of the present application, the light transmittance of the first display area AA1 is greater than the light transmittance of the second display area AA2, so that the photosensitive component may be integrated on the back of the first display area AA1 of the display panel 200 to achieve under-screen integration of the photosensitive component (such as, image acquisition equipment), while the first display area AA1 can display pictures. Thus, the display area of the display panel 200 can be increased and a full-screen design of a display apparatus can be realized.

A combination of graphic parameters and position parameters of first electrodes in the first display area AA1 enables a ratio of zero-order diffraction spot energy of the display panel to light transmission energy of the display panel to be greater than or equal to 85%, i.e., a proportion of the zero-order diffraction spot energy can be increased and a proportion of non-zero-order diffraction spot energy can be decreased. Therefore, the diffraction phenomenon of the light-transmitting display area can be mitigated, and a photosensitive quality of a photosensitive component (for example, a camera) integrated under the screen can be improved.

Exemplarily, the display panel 200 may further include an encapsulation layer and a polarizer and a cover plate positioned above the encapsulation layer. Alternatively, the cover plate may be directly arranged at least above the encapsulation layer of the first display area AA1 without a need for the polarizer, in order to avoid the polarizer's affecting light collection amount of corresponding photosensitive elements arranged under the first display area AA1. Of course, the polarizer may also be arranged above the encapsulation layer of the first display area AA1.

The above-mentioned embodiments of the present application do not describe all details exhaustively, nor do they limit the scope of the application. Obviously, according to the above description, many modifications and changes can be made by those skilled in the art. This specification describes these embodiments in details, in order to better explain principles and practical applications of this application, so that those skilled in the art can make good use of this application and make modifications on the basis of this application. This application is only limited by the appended claims.

What is claimed is:

1. A light-transmitting display panel, comprising:
an array substrate; and
a light-emitting layer positioned on the array substrate, the light-emitting layer comprising a plurality of pixel units each pixel unit comprising a plurality of sub-pixels each having a first electrode, the first electrodes of the sub-pixels in the plurality of pixel units being arranged in a pattern, the plurality of first electrodes arranged in the pattern having a combination of graphic parameters and position parameters, and zero-order diffraction spot energy of the light-transmitting display panel and light transmission energy of the light-transmitting display panel satisfying a following relationship expression:
$$\frac{{I}_{0}}{{I}_{x}} \geq 85 \%$$
wherein I₀ represents the zero-order diffraction spot energy of the light-transmitting display panel, and Iₓ represents the light transmission energy of the light-transmitting display panel.

2. The light-transmitting display panel of claim 1, wherein each of the plurality of pixel units comprises a first pixel group and a second pixel group distributed along a first direction, the first pixel group comprises a first color sub-pixel, a second color sub-pixel, and a third color sub-pixel distributed along a second direction, the second pixel group comprises a third color sub-pixel, a first color sub-pixel, and a second color sub-pixel distributed along the second direction, and the first direction intersects the second direction;
Wherein a shape of an orthographic projection of a first electrode of the first color sub-pixel and a shape of an orthographic projection of a first electrode of the third color sub-pixel on the array substrate are circles, and a shape of an orthographic projection of a first electrode of the second color sub-pixel on the array substrate is an ellipse.

3. The light-transmitting display panel of claim 2, wherein a diameter of the first electrode of the first color sub-pixel ranges from 5 μm to 25 μm, a diameter of the first electrode of the third color sub-pixel ranges from 8 μm to 30 μm, a long axis of the first electrode of the second color sub-pixel ranges from 10 μm to 30 μm, and a short axis of the first electrode of the second color sub-pixel ranges from 8 μm to 20 μm.

4. The light-transmitting display panel of claim 2, wherein a distance from a central point of the first electrode of the first color sub-pixel in the first pixel group to a central point of the pixel unit in the first direction ranges from 10 μm to 30 μm, a distance from the central point of the first electrode of the first color sub-pixel in the first pixel group to the central point of the pixel unit in the second direction ranges from 45 μm to 65 μm, a distance from a central point of the first electrode of the second color sub-pixel in the first pixel group to the central point of the pixel unit in the first direction ranges from 25 μm to 40 μm, a distance from the central point of the first electrode of the second color sub-pixel in the first pixel group to the central point of the pixel unit in the second direction ranges from 20 μm to 40 μm, a distance from a central point of the first electrode of the third color sub-pixel in the first pixel group to the central point of the pixel unit in the first direction ranges from 10 μm to 30 μm, and a distance from the central point of the first electrode of the third color sub-pixel in the first pixel group to the central point of the pixel unit in the second direction ranges from 15 μm to 30 μm.

5. The light-transmitting display panel of claim 2, wherein a distance from a central point of the first electrode of the first color sub-pixel in the second pixel group to a central point of the pixel unit in the first direction ranges from 10 μm to 25 μm, a distance from the central point of the first electrode of the first color sub-pixel in the second pixel group to the central point of the pixel unit in the second direction ranges from 10 μm to 20 μm, a distance from a central point of the first electrode of the second color sub-pixel in the second pixel group to the central point of the pixel unit in the first direction ranges from 25 μm to 40 μm, a distance from the central point of the first electrode of the second color sub-pixel in the second pixel group to the central point of the pixel unit in the second direction ranges from 30 μm to 50 μm, a distance from a central point of the first electrode of the third color sub-pixel in the second pixel group to the central point of the pixel unit in the first direction ranges from 25 μm to 40 μm, and a distance from the central point of the first electrode of the third color sub-pixel in the second pixel group to the central point of the pixel unit in the second direction ranges from 40 μm to 55 μm.

6. The light-transmitting display panel of claim 1, wherein each of the pixel units comprises two pixel groups distributed along a second direction, each of the pixel groups comprises one first color sub-pixel, one second color sub-pixel, and one third color sub-pixel, central points of first electrodes of the three sub-pixels in each of the pixel groups, when connected by lines, form a triangle, an arrangement structure of one of the pixel groups after being inverted by 180 degrees in a first direction is identical to an arrangement structure of the other one of the pixel groups in the pixel unit, and the first direction intersects the second direction;
wherein a shape of an orthographic projection of a first electrode of each sub-pixel on the array substrate is a circle.

7. The light-transmitting display panel of claim 6, wherein a diameter of a first electrode of the first color sub-pixel ranges from 5 μm to 25 μm, a diameter of a first electrode of the second color sub-pixel ranges from 10 μm to 30 μm, and a diameter of a first electrode of the third color sub-pixel ranges from 10 μm to 30 μm.

8. The light-transmitting display panel according to claim 6, wherein a distance between every two central points of first electrodes of the first color sub-pixel, second color sub-pixel, and third color sub-pixel in each of the pixel groups is 15 μm to 50 μm, and/or the central points of first electrodes of the first color sub-pixel, second color sub-pixel, and third color sub-pixel in each of the pixel groups, when connected by lines, form an isosceles triangle or an equilateral triangle.

9. The light-transmitting display panel of claim 1, wherein each of the pixel units comprises two pixel groups distributed along a second direction, each of the pixel groups comprises one first color sub-pixel, one second color sub-pixel, and one third color sub-pixel, central points of first electrodes of the three sub-pixels in each of the pixel groups, when connected by lines, form a triangle, an arrangement structure of one of the pixel groups after being inverted by 180 degrees in a first direction is identical to an arrangement structure of the other one of the pixel groups in the pixel unit, and the first direction intersects the second direction;
wherein shapes of an orthographic projection of a first electrode of the first color sub-pixel and a shape of an orthographic projection of a first electrode of the third color sub-pixel on the array substrate are circles, a shape of an orthographic projection of a first electrode of the second color sub-pixel on the array substrate is an octagon, and virtual extension lines of four sides of the octagon constitute a rectangle.

10. The light-transmitting display panel of claim 9, wherein a diameter of the first electrode of the first color sub-pixel ranges from 5 μm to 25 μm, a diameter of the first electrode of the third color sub-pixel ranges from 10 μm to 30 μm, a long side and a short side of a rectangle corresponding to the first electrode of the second color sub-pixel range from 10 μm to 30 μm and 5 μm to 25 μm, respectively.

11. The light-transmitting display panel of claim 9, wherein a distance between central points of first electrodes of two first color sub-pixels is 30 μm to 90 μm, a distance between central points of first electrodes of two second color sub-pixels is 25 μm to 60 μm, a distance between central points of first electrodes of two third color sub-pixels is 25 μm to 60 μm; and/or the central points of the first electrodes of the two first color sub-pixels and the central points of the first electrodes of the two third color sub-pixels, when connected by lines, constitute a parallelogram.

12. The light-transmitting display panel of claim 1, wherein each of the pixel units comprises a first pixel group and a second pixel group distributed along a second direction, the first pixel group comprises one first color sub-pixel, two second color sub-pixels, and one third color sub-pixel distributed along a first direction, the second pixel group comprises one third color sub-pixel, one first color sub-pixel, and two second color sub-pixels distributed along the first direction, the two second color sub-pixels in each of the first pixel group and the second pixel group are distributed along the second direction, and the first direction intersects the second direction;
wherein a shape of an orthographic projection of a first electrode of each sub-pixel on the array substrate is a circle.

13. The light-transmitting display panel of claim 12, wherein a diameter of a first electrode of the first color sub-pixel ranges from 5 μm to 30 μm, a diameter of a first electrode of each second color sub-pixel ranges from 5 μm to 30 μm, and a diameter of a first electrode of the third color sub-pixel ranges from 10 μm to 40 μm.

14. The light-transmitting display panel according to claim 13, wherein a distance between central points of first electrodes of two first color sub-pixels is 50 μm to 250 μm, a distance between central points of first electrodes of the two second color sub-pixels in each pixel group is 10 μm to 30 μm, a distance between central points of first electrodes of two third color sub-pixels is 10 μm to 60 μpm; and/or the pixel unit as a whole constitutes a parallelogram.

15. A display panel comprising a first display area and a second display area adjacent to each other, light transmittance of the first display area being greater than light transmittance of the second display area, wherein the first display area of the display panel is configured to be the light-transmitting display panel of claim 1.

16. A method for optimizing a pixel arrangement, comprising:
constructing an initial pixel arrangement structure model, a first electrode of each sub-pixel in the initial pixel arrangement structure model having an initial graphic parameter and an initial position parameter; and
adjusting at least one of initial graphic parameters and initial position parameters of at least a part of first electrodes in the initial pixel arrangement structure model to obtain an optimized pixel arrangement structure model of the light-transmitting display panel of claim 1, a ratio of zero-order diffraction spot energy of the optimized pixel arrangement structure model to light transmission energy of the optimized pixel arrangement structure model being greater than or equal to 85%.

17. The method of claim 16, wherein after obtaining the optimized pixel arrangement structure model, the method further comprises:
setting a graphic parameter and a position parameter for each first electrode in a target light-transmitting display panel, according to a corresponding graphic parameter and position parameter of a corresponding first electrode in the optimized pixel arrangement structure model.

18. The method of claim 16, wherein constructing the initial pixel arrangement structure model comprises:
acquiring a pixel arrangement structure of a target light-transmitting display panel and an initial graphic parameter and an initial position parameter of a first electrode of each sub-pixel of the target light-transmitting display panel; and
constructing the initial pixel arrangement structure model, according to the pixel arrangement structure of the target light-transmitting display panel and the initial graphic parameter and the initial position parameter of the first electrode of each sub-pixel of the target light-transmitting display panel.

19. The method of claim 16, wherein adjusting at least one of initial graphic parameters and initial position parameters of at least a part of first electrodes in the initial pixel arrangement structure model to obtain the optimized pixel arrangement structure model, a ratio of zero-order diffraction spot energy of the optimized pixel arrangement structure model to light transmission energy of the optimized pixel arrangement structure model is greater than or equal to 85% comprises:
determining whether a ratio of zero-order diffraction spot energy of the initial pixel arrangement structure model to light transmission energy of the initial pixel arrangement structure model is greater than or equal to 85% or not under conditions of different irradiation wavelengths, fields of view, and object distances;
under a condition that the ratio is not greater than or equal to 85%, adjusting continuously at least one of the initial graphic parameters and the initial position parameters of at least a part of the first electrodes in the initial pixel arrangement structure model, until the optimized pixel arrangement structure model is obtained, enabling the ratio of the zero-order diffraction spot energy of the optimized pixel arrangement structure model to the light transmission energy of the optimized pixel arrangement structure model to be greater than or equal to 85% under the conditions of different irradiation wavelengths, fields of view, and object distances.
